(19) United States
(12) Patent Application Publication
(10) Pub. No.: US 2014/0318741 A1
(43) Pub. Date: Oct. 30, 2014

(54) Cooling With Liquid Coolant And Bubble Heat Removal

(71) Applicants: Nicholas Jeffers, Delgany (IE); Brian Donnelly, Swords (IE); John Daly, Tralee (IE)

(72) Inventors: Nicholas Jeffers, Delgany (IE); Brian Donnelly, Swords (IE); John Daly, Tralee (IE)

(21) Appl. No.: 13/930,900

(22) Filed: Jun. 28, 2013

Related U.S. Application Data
(60) Provisional application No. 61/817,281, filed on Apr. 29, 2013.

(51) Int. Cl. H05K 7/20

(52) U.S. Cl. CPC H05K 7/20236
USPC 165/80.4

(57) ABSTRACT

An apparatus includes a reservoir to hold a volume of liquid, a port to inject a flow of gas into a lower portion of the reservoir, and a structure to transform the flow of gas into one or more streams of bubbles in said liquid. The reservoir has a port for injecting the gas into a lower region of the volume of liquid and has a top opening to release the injected gas therefrom. The apparatus includes one or more active electronic or optical devices located in the reservoir or located physically adjacent and in thermal contact with the reservoir such that the volume of the liquid is able to absorb part of heat produced by the one of more electronic or optical devices.

This application claims the benefit of provisional application 61/817281, filed Apr. 29, 2013.

### BACKGROUND

1. Technical Field

The invention relates generally to apparatus and processes for providing thermal cooling and to devices and methods using such apparatus and/or processes.

2. Discussion of the Related Art

This section introduces aspects that may be helpful to facilitating a better understanding of the inventions. Accordingly, the statements of this section are to be read in this light and are not to be understood as admissions about what is in the prior art or what is not in the prior art.

Active electronic devices often include one or more external heat sinks to provide cooling. In particular, a heat sink provides a structure that conducts generated heat away from the hot electronic device. A heat sink also provides a structure for transferring such heat to an ambient medium such as air. A heat sink is typically largely formed of one or more highly thermally conductive material such as one or more metals. A heat sink may also include spatially extended structures such as fin(s) or fin arrays to aid in the transfer of heat to a surrounding ambient medium.

### SUMMARY OF SOME ILLUSTRATIVE EMBODIMENTS

An embodiment of an apparatus includes a reservoir configured to hold a volume of liquid, a port located to inject a flow of gas into a lower portion of the reservoir, and a structure configured to transform the flow of gas into one or more streams of bubbles in said liquid. The reservoir has a port for injecting the gas into a lower region of the volume of liquid and has a top opening to release the injected gas therefrom. The apparatus also includes one or more active electronic or optical devices located in the reservoir or located physically adjacent and in thermal contact with the reservoir such that the volume of the liquid is able to absorb part of heat produced by the one of more electronic or optical devices.

In some embodiments of the above apparatus, said structure may be configured produce the bubbles with diameters of about 2 millimeters or less or of about 1 millimeter or less.

In some embodiments of the above apparatus, the structure may include a layer having an array of perforations there through, and the tube may be connected deliver the flow of gas to a surface of the layer. The layer may be able to disrupt the flow of gas to produce bubbles having diameters of about 2 millimeters or less in the liquid.

In some embodiments of any of the above apparatus, the apparatus may further include a pump connected to pump said gas through said tube into the reservoir.

In some embodiments of any of the above apparatus, the structure may include a porous structure, and the tube may be connected to direct the flow of gas into the porous structure to form therefrom the one or more streams of bubbles of the gas. The porous structure may be able to disrupt the flow of gas into the one or more streams of bubbles such that the bubbles have diameters of about 1 millimeter or less. The apparatus may further include a pump connected to pump said gas through said tube.

In some embodiments of any of the above apparatus, the apparatus may include said volume of liquid located in said reservoir. The liquid may be a dielectric liquid.

In some embodiments of any of the above apparatus, the apparatus may be configured to dissipate at least ½ of the heat generated by the one or more electronic or optical devices during operation thereof.

In some embodiments of any of the above apparatus, the apparatus may further include a blower configured to move said released gas away from the reservoir.

In some embodiments of any of the above apparatus, the apparatus may further include a chimney connected to inject the flow of gas into the port, wherein a top of the chimney is as high as the reservoir.

In some embodiments, a method of cooling heat sources includes conducting heat for the heat sources into a volume of fluid located in a reservoir, producing streams of bubbles of gas that rise through the volume of fluid, and bursting the bubbles at a top surface of the volume such that the gas therein is released from the volume and the reservoir.

In some embodiments of the above method, the method may further include operating a blower to move some of the released gas away from the volume of fluid.

Some embodiments of the any of the above methods may further include passing the gas through a chimney such that the gas enters a bottom portion of reservoir, a top portion of the chimney being above the top surface of the volume.

### BRIEF DESCRIPTION OF THE FIGURES

FIG. 1 schematically illustrates an apparatus that provides cooling via a liquid coolant and heat removal from the liquid coolant via one or more streams of gas bubbles;

FIG. 2A schematically illustrates a specific embodiment of the structure for producing the one or more streams of bubbles in the apparatus of FIG. 1;

FIG. 2B schematically illustrates another specific embodiment of the structure for producing the one or more streams of bubbles in the apparatus of FIG. 1;

FIG. 3 schematically illustrates an embodiment of the apparatus of FIG. 1 that includes a chimney for injecting a flow of gas into a lower portion of the reservoir;

FIG. 4 is a flow chart that schematically illustrates a method for providing cooling via a volume of liquid coolant, which is, at least, partly cooled by streaming bubbles there through, e.g., in any of the apparatus of FIG. 1, 2A, 2B, or 3.

In the Figures and text, like reference numbers refer to structurally and/or functionally similar elements.

In the Figures, relative dimensions of some features may be exaggerated to more clearly show one or more of the structures being illustrated therein.

Herein, various embodiments are described more fully by the Figures and the Detailed Description of Illustrative Embodiments. Nevertheless, the inventions may be embodied in various forms and are not limited to the specific embodiments that are described in the Figures and Detailed Description of Illustrative Embodiments.

### DESCRIPTION OF THE ILLUSTRATIVE EMBODIMENTS

U.S. provisional application 61/817281, filed Apr. 29, 2013, is incorporated by reference herein in its entirety.

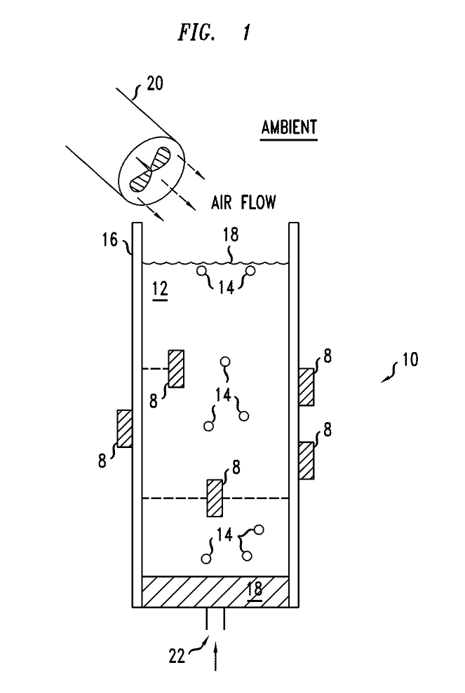

FIG. 1 schematically illustrates an apparatus 10 that provides cooling via a bubble-cooled volume 12 of liquid coolant. The apparatus 10 includes a reservoir 16, which holds the volume 12 of liquid coolant, and one or more structures 18 to introduce bubbles 14 of gas into the volume 12 of liquid coolant in the reservoir 16. The volume 12 of liquid coolant absorbs heat from heat sources 8, e.g., active electronic and/or optical devices, which may be physically suspended in the volume 12 of liquid coolant (e.g., rigidly suspended as shown by dotted lines in FIG. 1) and/or may be located external and adjacent to the reservoir 16 and in physical contact with thermally conductive wall(s) of the reservoir 16. Typically, a short and low resistance thermal path thermally couples any such heat sources 8, which are external to the reservoir 16 to the volume 12 of liquid coolant in the reservoir 16. That is, the reservoir 16 functions as a liquid coolant-to-bubble 14 of gas heat exchanger.

During operation, the liquid coolant has a temperature that is higher than the initial temperature of the gas of the bubbles 14. Thus, heat is transferred from the hot liquid coolant of the volume 12 to the initially cooler bubbles 14 of gas. While rising and/or moving through the volume 12 of the liquid coolant, the bubbles 14 absorb more heat from the liquid coolant.

Typically, the gas bubbles 14 are fabricated with small diameters to have high surface area-to-volume ratios. When a gas bubble's surface area-to-volume ratio is high, the gas may more efficiently and rapidly absorb heat from adjacent liquid coolant 12 of higher temperature. For example, the gas bubbles 14 often have diameters of less than 2 millimeters (2 mm) and may have diameters of 1 mm or less. Such small gas bubbles 14 typically travel in roughly straight lines while rising through the volume 12 of liquid coolant. The motion of such small gas bubbles 14 is characterized as having a low Reynolds number, e.g., less than about 200. The flow of such small gas bubbles 14 is also typically substantially laminar and thus, does not produce significant numbers of vortices in the volume 12 of liquid coolant.

Due to buoyancy forces, the bubbles 14 of gas rise to top exterior surface 18 of the volume 12 of liquid coolant. At the top exterior surface 18, the gas bubbles 14 burst releasing hot gas thereof to the exterior of the volume 12 of liquid coolant. Since the top of the reservoir 16 is open, the released hot gas may be carried away from the reservoir 16. Thus, the bursting of the bubbles 14 of hot gas at the top exterior surface 18 can cool the liquid coolant of the volume 12. In some embodiments, an optional gas blower 20 moves such hot gas away from the volume 12 of liquid coolant thereby dissipating some of the heat of said gas in surrounding ambient, e.g., air.

In the volume 12, the liquid coolant may be any liquid suitable for absorbing heat from a hot body. For example, the liquid coolant may be an organic dielectric liquid, e.g., a hydro-fluorocarbon (HFC) refrigerant liquid such as 1,1,1,2-Tetrafluoroethane (also known as R134a), or may be a polar coolant liquid, e.g., water. The liquid coolant typically has a high heat capacity to enable adequate absorption of heat from the heat sources 8, which are being cooled, e.g., sufficient to avoid unsuitably hot spots on such heat sources 8. Also, the liquid coolant typically does not have a high viscosity, e.g., a low or moderate viscosity, so that buoyancy forces may move the bubbles 14 of gas through the volume of liquid coolant 12 at a sufficient speed to provide for adequate cooling.

The bubbles 14 may be formed of any gas with, at least, a moderate heat capacity. For example, the bubbles 14 may be air bubbles, helium bubbles, etc. The bubbles 14 are buoyant in the liquid coolant at ordinary operating temperatures. Due, at least, in part to their buoyancy, the bubbles 14 rise through the volume 12 of liquid coolant to the top external surface 18 thereof. The motion of the bubbles 14 may also be affected by the form of the reservoir and/or the injection speed of gas into the bottom portion of the reservoir 16.

The reservoir 16 has a bottom and one or more sides constructed to hold the volume 12 of liquid coolant without leaking. Thus, the bottom and one or more sides are typically impermeable to the liquid coolant. Of example, the reservoir may be fabricated of a metal with high heat conductivity, e.g., aluminum. The bottom and/or lower portion of the side(s) include(s) one of more inputs for the bubbles 14 of gas, wherein the input(s) are configured to avoid leaking of the liquid coolant from the reservoir 1 during operation.

Various embodiments include different structures 18 for injecting the bubbles 14 of gas into the volume 12 of coolant liquid of the reservoir 16. The gas may enter the reservoir 16 via one or more ports 22 that are configured to stop leakage of the coolant liquid from the reservoir 16.

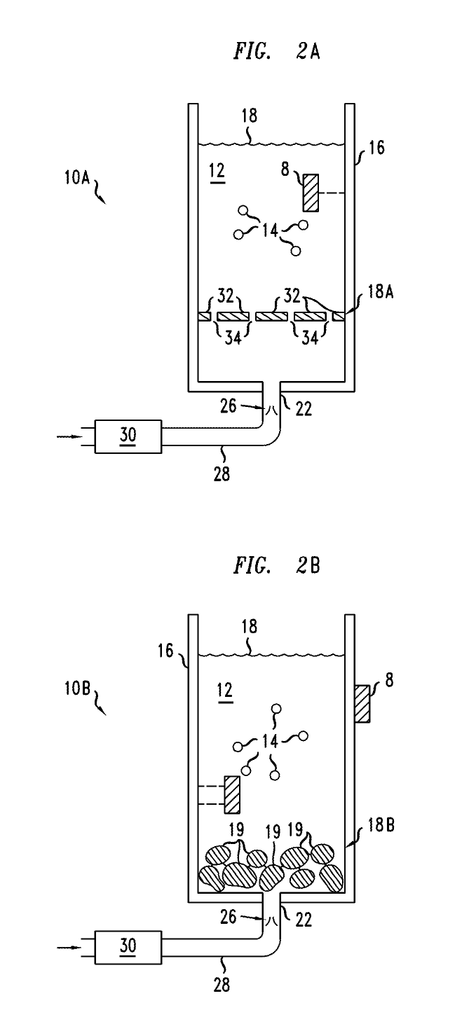

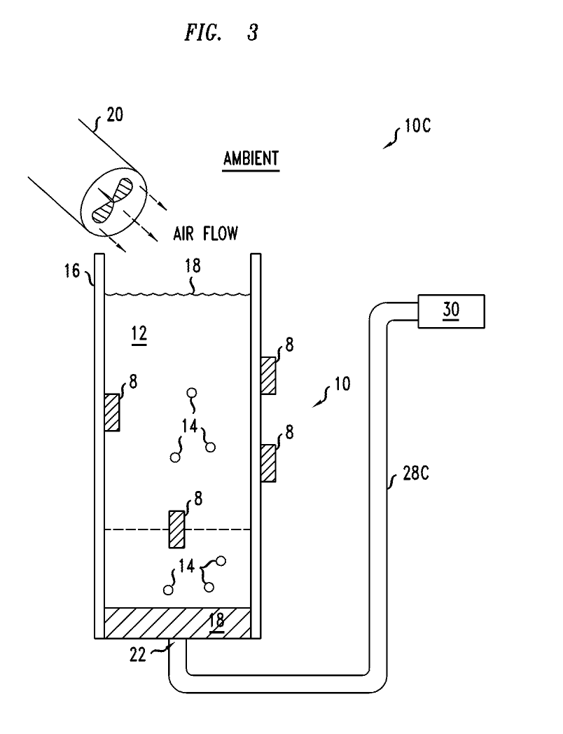

FIGS. 2A, 2B and 3 illustrate three alternate embodiments 10A, 10B, 10C of the apparatus 10 of FIG. 1. Each apparatus 10A, 10B, 10C includes the reservoir 16, the volume 12 of liquid coolant therein, and different embodiments of the one or more structures 18.

Referring to FIG. 2A, the one or more structures 18 include a sequence formed by a gas-flow disrupter 18A connected in parallel to one or more of the ports 22.

Each port 22 includes a one-way valve 26 configured to allow the gas to enter into the bottom of the gas-flow disrupter 18A without allowing the coolant liquid 12 to leak from the reservoir 16 via the port 22. Each one-way valve 26 may connect via a tube 28 to a gas pump 30, which is connected to pump the gas through the one-way valve 26. Alternately, each one-way valve 26 may be operated by a suction or negative pressure.

The gas-flow disrupter 18A physically disrupts gas-flow from the one or more one-way valves 26, e.g., to produce quasi-parallel streams of the bubbles 14 of gas, which rise in the volume 12 of liquid coolant of the reservoir 16. The gas-flow disrupter 18 includes one or more layers 32, wherein each layer 32 has an array of perforations 34 there through. Thus, each layer 32 obstructs the gas-flow by causing the gas to pass through the perforations 34 of small size in the layer 32. Restricting the gas to flow through the perforations breaks up the gas-flow into separate smaller gas flows thereby producing quasi-parallel streams of bubbles 14 of the gas in the liquid coolant of the reservoir 16. For example, the gas-flow disrupter 18A may produce the bubbles 14 of gas with diameters of less than 2 millimeters or even less than about 1 millimeter.

The gas-flow disrupter 18A may be formed by one wire mesh or a stack of wire meshes. Each wire mesh has a small mesh size to disrupt the input gas-flow into parallel streams of small bubbles of gas.

Alternately, the gas-flow disrupter 18A may be formed by a continuous rigid layer that has a regular or irregular array of perforations there through. During operation, each perforation can inject a stream of the bubbles 14 of gas into the volume 12 of the liquid coolant. Thus, the array produces quasi-parallel streams of such bubbles 14 of gas.

Referring to FIG. 2B, the one or more structures 18 include a porous structure 18B, which partially or completely separates the gas flow from the one or more ports 22 into a collection of smaller quasi-parallel gas flows. The porous structure 18B may be formed of tightly-packed small objects 19, e.g., spheres of 200 micrometers in diameter, which have been sintered or otherwise physically attached to form a solid porous object.

In some embodiments, the one or more structures 18 may include a sequence having one or more the perforated layers 18A, as described with respect to FIG. 2A, and one or more of the porous structures 18B, as described with respect to FIG. 2B.

In various embodiments, the one or more structures 18 and one or more ports 22 may be located along the bottom and/or lower portion of the side(s) of the reservoir 16.

FIG. 3 illustrates an embodiment 10C of the apparatus 10 of FIG. 1 that does not include the one or more one-way valves 26 of FIGS. 2A-2B. Each apparatus 10C, 10B includes the reservoir 16, the volume 12 of liquid coolant therein, and different the one or more structures 18.

Rather than the one-way valve 26, the apparatus 10C includes a chimney 28C, which has a lower end connected to the port 22 and has an upper end connected to an output of the gas pump 30. The pump 30 forces gas through the chimney 28C into the bottom or lower side of the reservoir 16 by the port 22. The upper end of the chimney 28C is located above the upper surface 18 of the liquid coolant in the reservoir 16. Thus, the connection to the bottom or lower side of the reservoir 16 does not cause the liquid coolant to leak away even in the absence of a one-way valve in the chimney 28C. Instead, when the pump 30 is off, the liquid coolant may occupy a segment of the chimney 28C without leaking therefrom.

In various embodiments, the apparatus 10C may include embodiments of the one or more structures 18 as described with respect to the apparatus 10A, 10B of FIGS. 10A-10B.

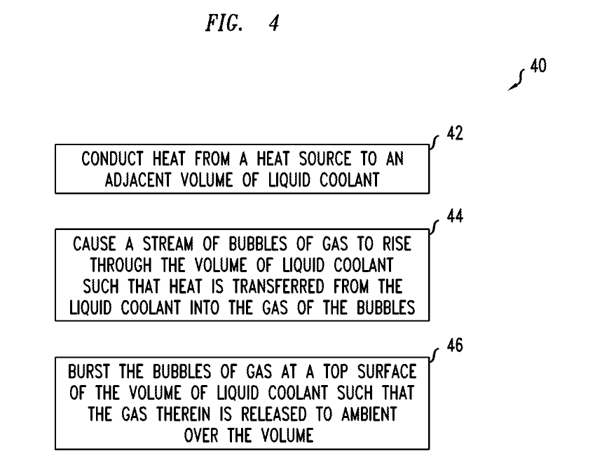

FIG. 4 is a flow chart that schematically illustrates a method 40 for providing cooling via a liquid coolant that is itself cooled via gas bubbles, e.g., in any of the apparatus 10, 10A, 10B, 10C of FIGS. 1, 2B, 2B, and 3.

The method 40 includes conducting heat from a heat source, e.g., any of the heat sources 8 of FIGS. 1, 2A, 2B, and 3, to a volume of liquid coolant (step 42). For example the liquid coolant located in the reservoir 16 of FIG. 1, 2A, 2B, or 3.

The method 40 includes causing a stream of bubbles of gas, e.g., the bubbles 14 of FIGS. 1, 2A, 2B, and 3, to rise through the volume of liquid coolant such that heat is transferred from the liquid coolant into the gas of the bubbles (step 44).

The method 40 includes having the bubbles of gas burst at a top surface of the volume of liquid coolant such that the gas therein is released to ambient over the volume (step 46).

In some embodiments, the method 40 may include operating a blower to move the hot gas from the burst bubbles away from the volume of liquid coolant.

In some embodiments, the method 40 may include passing the gas through a condenser to condense coolant carried by the gas released from the burst bubbles. Such condensed coolant may be returned to the volume of liquid coolant to reduce losses of liquid therefrom.

In some embodiments, the apparatus 10, 10A, 10B, and 10C of FIGS. 1, 2A, 2B, and/or 3 may include a conventional apparatus for condensing coolant, which is carried in the released gas and for returning said condensed coolant to the volume 10. Some other embodiments of the apparatus 10, 10A, 10B, and 10C do not include such a condenser. Instead, liquid coolant may be periodically added to the reservoir 16 to compensate for losses of coolant in the released gas.

In various embodiments, the reservoir 16 of FIGS. 1, 2A, 2b, and 3, which a liquid-gas heat exchanger, may have a smaller volume and/or weight than other apparatus that do not use streams of bubbles of gas to remove heat from liquid coolant. Indeed, the small volume of liquid coolant may be adequate to provide for substantial cooling of electronic or optical heat sources, e.g., the heat sources 8 of FIGS. 1, 2A, 2B, and 3.

In some embodiments, the reservoir of 16 FIGS. 1, 2A, 2b, and 3 may also include other apparatus for cooling the liquid therein. The other structures may include one or more heat-conducting fins, e.g., metal fins, along one or more external surfaces of the reservoir.

In various embodiments of the apparatus 10, 10A, 10B, and/or 10C of FIGS. 1, 2A, 2B, and 3, the liquid coolant may be able or configured to dissipate at least ½ of the heat produced by the heat sources, e.g., active electronic or optical devices, during operation of said sources. In such embodiments, the bubbles may be able to provide substantial cooling to the liquid coolant.

The invention is intended to include other embodiments that would be obvious to one of skill in the art in light of the description, figures, and claims.

What we claim is:

1. An apparatus comprising:
a reservoir being configured to hold a volume of liquid, the reservoir having a port for injecting gas into a lower region of the volume of liquid and having a top opening to release the injected gas therefrom;
a port located to inject a flow of gas into a lower portion of the reservoir,
a structure configured to transform the flow of gas into one or more streams of bubbles in said liquid; and
one or more active electronic or optical devices being located in the reservoir or being located physically adjacent and in thermal contact with the reservoir such that the volume of the liquid is able to absorb part of heat produced by the one of more electronic or optical devices.

2. The apparatus of claim 1, wherein said structure is configured produce the bubbles with diameters of about 2 millimeters or less.

3. The apparatus of claim 1, wherein said structure is configured produce the bubbles with diameters of about 1 millimeter or less.

4. The apparatus of claim 1, wherein the structure includes layer having an array of perforations there through and the tube is connected deliver the flow of gas to a surface of the layer.

5. The apparatus of claim 4, wherein the layer is able to disrupt the flow of gas to produce bubbles having diameters of about 2 millimeters or less in the liquid.

6. The apparatus of claim 1, further comprising a pump connected to pump said gas through said tube into the reservoir.

7. The apparatus of claim 1, wherein the structure includes a porous structure, the tube being connected to direct the flow of gas into the porous structure to form therefrom streams of bubbles of the gas in the liquid.

8. The apparatus of claim 7, wherein the porous structure is able to disrupt the flow of gas into the streams of bubbles such that the bubbles have diameters of about 1 millimeter or less.

9. The apparatus of claim 7, further comprising a pump connected to pump said gas through said tube.

10. The apparatus of claim 2, further comprising said volume of liquid located in said reservoir.

11. The apparatus of claim 10, wherein the liquid is a dielectric liquid.

12. The apparatus of claim 2, wherein the apparatus is configured to dissipate at least ½ of the heat produced by the one of more electronic or optical devices during operation thereof.

13. The apparatus of claim 1, further comprising a blower configured to move said released gas away from the reservoir.

14. The apparatus of claim 1, further comprising a chimney connected to inject the flow of gas into the port, a top of the chimney being as high as the reservoir.

15. A method of cooling heat sources, comprising:
conducting heat for the heat sources into an adjacent volume of fluid located in a reservoir;
producing streams of bubbles of gas that rise through the volume of fluid;
bursting the bubbles at a top surface of the volume such that the gas therein is released from the volume and the reservoir.

16. The method of claim 15, further comprising operating a blower to move some of the released gas away from the volume of fluid.

17. The method of claim 15, further comprising passing the gas through a chimney such that the gas enters a bottom portion of reservoir, a top portion of the chimney being above the top surface of the volume.
